(19) United States
(12) Patent Application Publication
(10) Pub. No.: US 2020/0212141 A1
(43) Pub. Date: Jul. 2, 2020

(54) DISPLAY PANEL, ASSOCIATED DISPLAY SYSTEM, AND ASSOCIATED METHOD

(71) Applicant: INT TECH CO., LTD., HSINCHU COUNTY (TW)

(72) Inventor: KUO-CHENG HSU, TAICHUNG CITY (TW)

(21) Appl. No.: 16/232,502

(22) Filed: Dec. 26, 2018

(51) Int. Cl. H01L 27/32; G06F 3/041; G09G 3/36

(52) U.S. Cl. CPC H01L 27/3244; G09G 2310/0264; G09G 3/3611; G06F 3/0412

(57) ABSTRACT

A display panel is disclosed. The display panel includes a plurality of pixels arranged in a pixel array, a first selecting circuit, and a control circuit. The pixel array includes a plurality of rows. The first selecting circuit is coupled to the display panel, and includes a plurality of clusters of first switch. Each first switch couples to a row, and the plurality of clusters of first switch are arranged to be sequentially and repeatedly activated, wherein a number of the row is greater than a number of first switches in one cluster. The control circuit is coupled to the first selecting circuit, and arranged to sequentially provide a pulse signal to the display panel via a cluster of first switch being activated.

### BACKGROUND

With the growing need of larger display panel, the amount of gate lines and source lines installed within the panel are correspondingly increased. Accordingly, more circuits are required to control the gate lines and the source lines which consume a lot of area.

### SUMMARY OF THE INVENTION

Therefore, one of the objectives of the present disclosure is to provide a display panel, an associated display system applying the display panel, and an associated method to solve the aforementioned problems.

According to embodiment of the present disclosure, a display panel is disclosed. The display panel includes a plurality of pixels arranged in a pixel array, a first selecting circuit, and a control circuit. The pixel array includes a plurality of rows. The first selecting circuit is coupled to the display panel, and includes a plurality of clusters of first switch. Each first switch couples to a row, and the plurality of clusters of first switch are arranged to be sequentially and repeatedly activated, wherein a number of the row is greater than a number of first switches in one cluster. The control circuit is coupled to the first selecting circuit, and arranged to sequentially provide a pulse signal to the display panel via a cluster of first switch being activated.

According to embodiment of the present disclosure, a display panel is disclosed. The display panel includes a plurality of pixels arranged in a pixel array, a first selecting circuit, at least one signal generating circuit and a process circuit. The pixel array includes a plurality of rows. The first selecting circuit includes a plurality of first switches, wherein each first switch couples to a row in the pixel array. Each of the at least one signal generating circuit couples to at least a row in the pixel array via the first switches, and each of the at least one signal generating circuit is arranged to provide a pulse signal to the display panel, wherein a number of the rows in the pixel array is greater than a number of the at least one signal generating circuit. The process circuit is arranged to provide a control signal to the selecting circuit to activate a part of the plurality of switches and deactivate another part of the plurality of switches.

According to embodiment of the present disclosure, a display system is disclosed. The display system includes a display panel and a driver integrated circuit (IC). The display panel includes a plurality of pixels arranged in a pixel array, a first selecting circuit, and a control circuit. The pixel array includes a plurality of rows. The first selecting circuit is coupled to the display panel, and includes a plurality of clusters of first switch. Each first switch couples to a row, and the plurality of clusters of first switch are arranged to be sequentially and repeatedly activated, wherein a number of the row is greater than a number of first switches in one cluster. The control circuit is coupled to the first selecting circuit, and arranged to sequentially provide a pulse signal to the display panel via a cluster of first switch being activated. The driver IC is coupled to the display panel and arranged to provide an image data to the plurality of columns in the pixel array.

According to embodiment of the present disclosure, a method of a display panel is disclosed. The method includes arranging a plurality of pixels of the display array in a pixel array, wherein the pixel array includes a plurality of rows; coupling each of a plurality of clusters of first switch to a row in the pixel array; sequentially and repeatedly activating the plurality of clusters of first switch; and sequentially providing a pulse signal to the display panel via a cluster of first switch being activated; wherein a number of the row is greater than a number of first switches in one cluster.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating a display panel according to an embodiment of the present disclosure.

FIG. 2 is a diagram illustrating a circuit in a pixel according to an embodiment of the present disclosure.

FIG. 3 is a diagram illustrating a control circuit and a selecting circuit according to an embodiment of the present disclosure.

FIG. 4A is a diagram illustrating an operation of the control circuit and the selecting circuit shown in FIG. 3 according to an embodiment of the present disclosure.

FIG. 4B is a diagram illustrating a following operation of the control circuit and the selecting circuit shown in FIG. 3 according to an embodiment of the present disclosure.

FIG. 5 is a diagram illustrating a signal waveforms of signals generated by signal generating circuits according to an embodiment of the present disclosure.

FIG. 6 is a diagram illustrating an operation of the control circuit and the selecting circuit shown in FIG. 3 according to another embodiment of the present disclosure.

FIG. 7 is a diagram illustrating a display panel according to another embodiment of the present disclosure.

FIG. 8 is a diagram illustrating a circuit in a pixel according to another embodiment of the present disclosure.

FIG. 9 is a diagram illustrating selecting circuits and a control circuit according to an embodiment of the present disclosure.

FIG. 10A is a diagram illustrating an operation of the selecting circuit and the control circuit shown in FIG. 9 according to an embodiment of the present disclosure.

FIG. 10B is a diagram illustrating a following operation of the selecting circuit and the control circuit shown in FIG. 9 according to an embodiment of the present disclosure.

FIG. 11 is a diagram illustrating a structure of a display panel according to an embodiment of the present disclosure.

FIG. 12 is flowchart illustrating a method of a display panel according to an embodiment of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

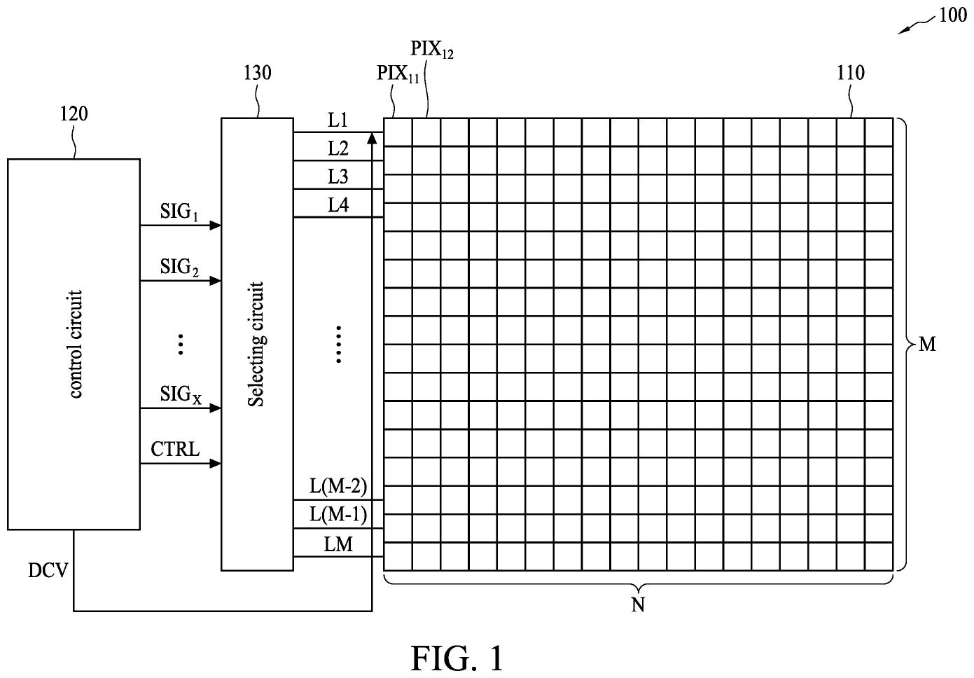

FIG. 1 is a diagram illustrating a display panel 100 according to an embodiment of the present disclosure. As shown in FIG. 1, the display panel 100 incudes a plurality of pixels arranged in a pixel array 110, a control circuit 120 and a selecting circuit 130. The pixel array 110 includes M rows and N columns, wherein M and N are both natural numbers. The pixel located in the first column and the first row is noted as the pixel PIX_{11I}, and the pixel located in the second column and the first row is noted as the pixel PIX₁₂, and so on. The selecting circuit 130 couples to the pixel array 110 via conductive lines L1 to LM as shown in FIG. 1, and each conductive line couples to the pixels located in the same row. The control circuit 120 is arranged to provide signals SIG₁ to SIG_{N}, and a control signal CTRL to the selecting circuit 130, wherein x is a natural number smaller than M. The control circuit 120 is further arranged to selectively provide a direct current (DC) voltage DCV to the pixel array 110 via the conductive lines L1 to LM.

For clarity and simplicity, only one signal line is depicted in FIG. 1 for the DC voltage DCV between the control circuit 120 and the conductive lines L1 to Lm. In some embodiments, each of the signals SIG₁ to SIG_{N} is a pulse signal. However, the profile of the signal SIG should not be limited by the present disclosure. Those skilled in the art should understand the pixels located in the same column may be coupled together with a conductive line as well. The conductive lines coupling the pixels located in the same column are omitted here in FIG. 1 for brevity.

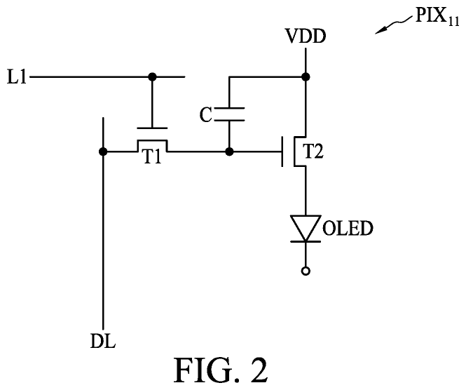

FIG. 2 is a diagram illustrating a circuit in each pixel according to an embodiment of the present disclosure. Take the pixel PIX₁₁ of the pixel array 110 for example, the pixel PIX₁₁ includes transistors T1 and T2, and a capacitor C. As shown in FIG. 2, a gate terminal of the transistor T1 is coupled to the conductive line L1. The conductive line L1 couples the gate terminals of the transistors T1 of pixels (e.g., the pixels PIX₁₁, and so on) located in the first row of the pixel array 110 together. Those skilled in the art should readily understand the conductive line L1 is characterized as a gate line, wherein a signal carried on the conductive line L1 determines the switch status of the transistor T1 during operating stages of the display panel 100. For example, when the display panel operates in a display stage, the signal carried on the conductive line L1 scans the pixels (e.g., the pixels PIX₁₁, PIX₁₂, and so on) located in the first row with a high voltage profile.

A source terminal of the transistor T1 is coupled to a conductive line DL, wherein the conductive line DL couples the source terminals of the transistors T1 of pixels located in the first column of the pixel array 110 together. Those skilled in the art should readily understand the conductive line DL is characterized as a data line, wherein the conductive line DL transmits image data to the pixel PIX₁₁ when the conductive line L1 switches on the transistor T1 during the display stage. In addition, the image data carried on the conductive line DL may he generated from a driver integrated circuit (IC) coupling to the display panel 100. Those skilled in the art should understand the driver IC and the display panel 100 constitute a display system.

A terminal of the capacitor C couples to a drain temrinal of the transistor T1 and a gate terminal of the transistor T2 while the other terminal of the capacitor C is coupledto a supply voltage VDD. When the transistor T1 is switched on, the signal carried on the conductive line DI. is transmitted to the drain terminal of the transistor T1 to switch on the transistor 12. As a result, an emission current passes through a drain terminal and the source terminal of the transistor T2. The capacitor C holds the voltage on the gate terminal of the transistor T2 at a certain level after the transistor Tl is switched off to maintain the emission current. Those skille in the art should readily understand an equivalent diode is formed on the source terminal of the transistor T2. In this embodiment, the display panel 100 applies Organic Light Emitting Diode (OLED) technology, and the diode is marked as OLED. When the emission current passes through the drain terminal and the source terminal of the transistor T2 to the diode OLED, the pixel PIX₁₁ correspondly illuminates.

It should be noted that the circuit shown in FIG. 2 is only for illustrative purpose, not a limitaiton of the present disclosure. Those skilled in the art should readily understand the circuit included in a pixel can have different topology. For example, a compensation circuit may be included in the pixel for compensating the decay of the OLED. In addition, in the embodiment of FIG. 2, the transistors T1 and T2 are depecited as N-type transistor. However, the transistors T1 and T2 can also be implemented by P-type transistor, and this should not be limited by the present disclosure.

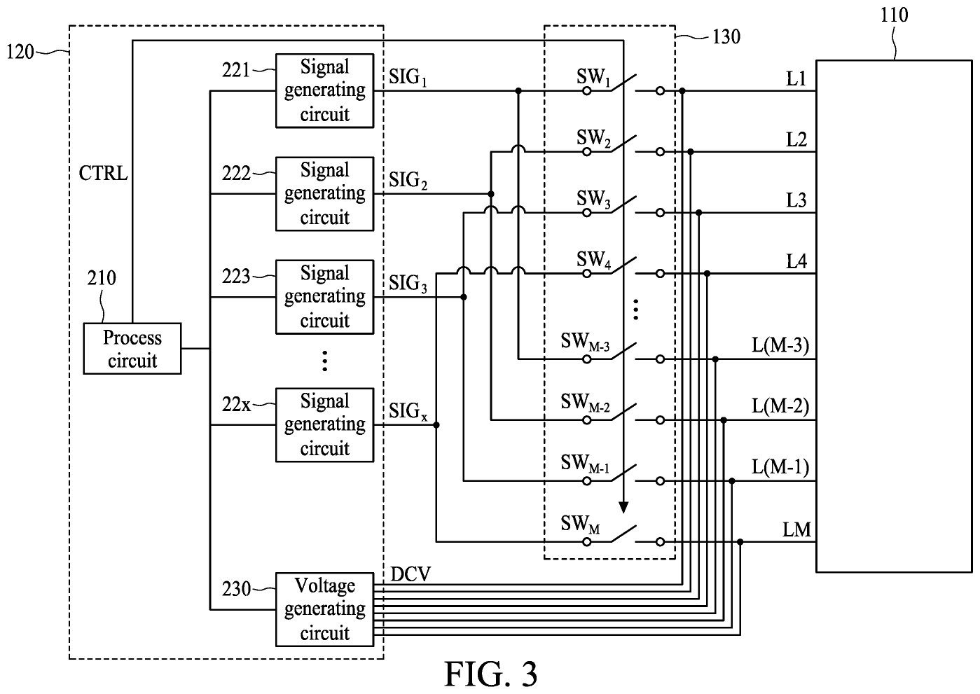

FIG. 3 is a diagram illustrating the control circuit 120 and a selecting circuit 130 according to an embodiment of the present disclosure. As shown in FIG. 3, the control circuit 120 includes a process circuit 210, signal generating circuits 221 to 22x, and a voltage generating circuit 230, wherein x is a natural number smaller than M as mentioned in FIG. 1. The selecting circuit 130 includes switches SW₁ to SW_{M}. The process circuit 210 is arranged to provide the control signal CTRL to selectively activate/deactivate the switches SW₁ to SW_{M} of the selecting circuit 130. Each of the signal generating circuits 221 to 22x is arranged to provide the corresponding signal SIG. In other words, the signal generating circuit 221 provides the signal SIG₁, and the signal generating circuit 222 provides the signal SIG₂, and so on.

As mentioned in the embodiment of FIG. 1, the signals SIG₁ to SIGₓ can be a pulse signal. Each of the switches SW₁ to SW_{M} corresponds to a row of the pixel array 100. In other words, the switch SW₁ couples to the first row of the pixel array 110 via the conductive line L1, and the switch SW₂ couples to the second row of the pixel array 110 via the conductive line L2, and so on. The voltage generating circuit 230 is arranged to selectively provide the DC voltage DCV to the pixel array 110 via the conductive lines L1 to Lm. The operations of the signal generating circuit 221 to 22x and the voltage generating circuit 230 is controlled by the process circuit 210. The connections between the signal generating circuits 221 to 22x and the switches SW₁ to SWₓ will be described later.

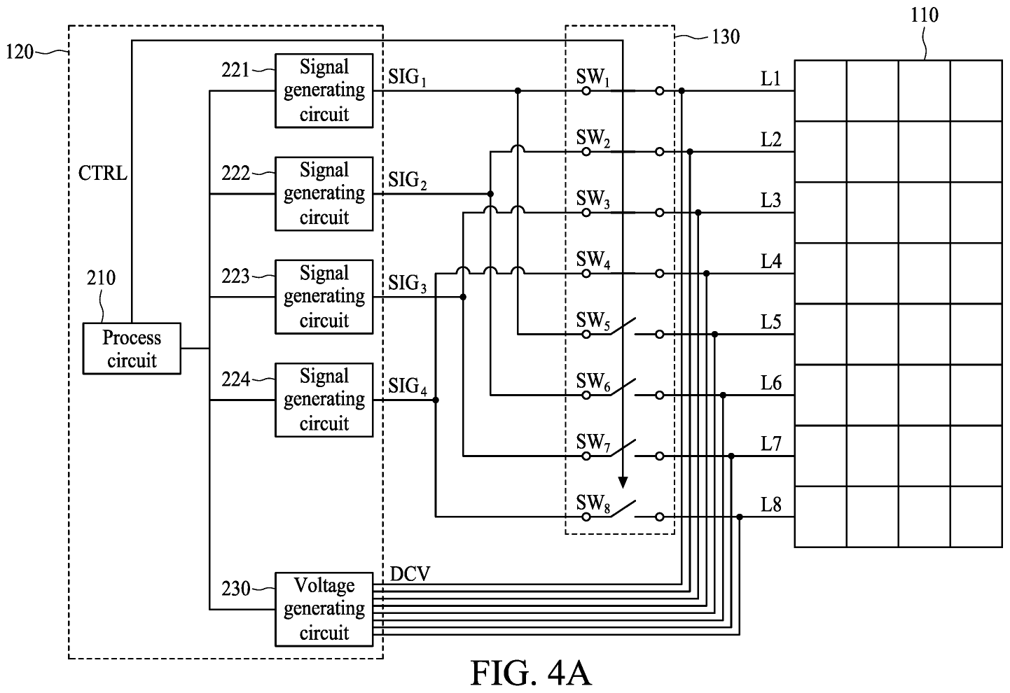

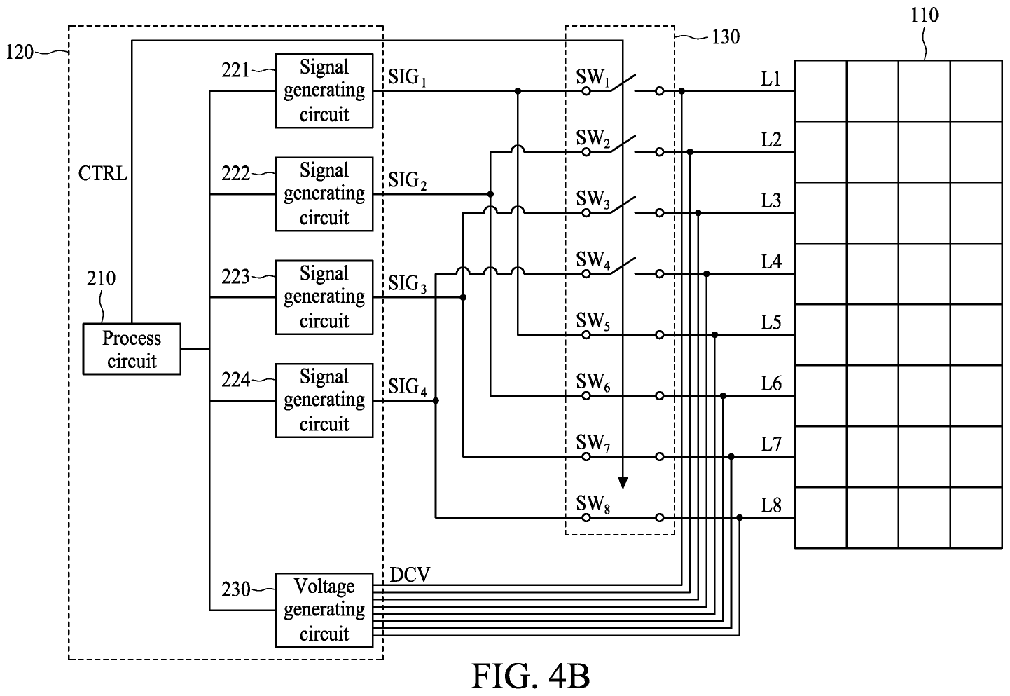

FIG. 4A is a diagram illustrating an operation of the control circuit 120 and the selecting circuit 130 shown in FIG. 3 according to an embodiment of the present disclosure. For clarity and simplicity, the natural number M is 8 and the natural number x is half of M (i.e., x=4). The signal generating circuit 221 is coupled to the first row and the fifth row of the pixel array 110 respecitve via the switch SW₁ (with the conductive line L1) and the switch SW₅ (with the conductive line L5). The signal generating circuit 222 is coupled to the second row and the sixth row of the pixel array 110 respecitve via the switch SW, (with the conductive line L2) and the switch SW₆ (with the conductive line L6). The signal generating circuit 223 is coupled to the third row and the seventh row of the pixel array 110 respecitve via the switch SW₃ (with the conductive line L3) and the switch SW₇ (with the conductive line L7). The signal generating circuit 224 is coupled to the fourth row and the eighth row of the pixel array 110 via respecitve the switch SW₄ (with the conductive line L4) and the switch SW₈ (with the conductive line L8). In this embodiment, since x is half of M (i.e., x=4), the switches SW₁ to SW₄ is categorized as a first cluster of switch while the switches SW₅ to SW₈ is categorized as a second cluster of switch.

More specifcally, the process circuit 210 provides the control signal CTRL to activate the first cluster of switch (i.e., the switches SW₁ to SW₄) and deactivate the second cluster of switch (i.e., the switches SW₅ to SW₈). As mentioned in the embodiments of FIG. 1 and FIG. 3, each of the signals SIG₁ to SIG₄ is a pulse signal. Therefore, with the activated switch SW₁, the transistors T1 located on the first row of the pixel array 110 is switched on when the signal SIG₁ is asserted. Likewise, with the activated switch SW₂, the transistors T1 of the pixels located on the second row of the pixel array 110 is switched on when the signal SIG₂ is asserted, and so on.

Meanwhile, the process circuit 210 controls the voltage generating circuit 230 to provide the DC voltage DCV to the second cluster of switch (i.e., the switches SW₅ to SW₈). In this embodiment, the DC voltage DCV may switch off the transistors T1 of the pixels located on the fifth row to the eighth row of the pixel array 110. With such configurations, the transistors T1 of the pixels located on the first row to the fourth row of the pixel array 110 are switched on, and the display data carried on the data line DL described in FIG. 2 can be transmitted to the first row to the fourth row of the pixel array 110.

Next, following the embodiment of FIG. 4A, FIG. 4B is a diagram illustrating a following operation of the control circuit 120 and the selecting circuit 130 shown in FIG. 3 according to an embodiment of the present disclosure, the process circuit 210 provides the control signal CTRL to activate the second cluster of switch (i.e., the switches SW₅ to SW₈) and deactivate the first cluster of switch (i.e., the switches SW₁ to SW₄). Therefore, with the activated switch SW₅, the transistors T1 located on the fifth row of the pixel array 110 is switched on when the signal SIG₅ is asserted. Likewise, with the activated switch SW₆, the transistors T1 of the pixels located on the sixth row of the pixel array 110 is switched on when the signal SIG₆ is asserted, and so on.

Meanwhile, the process circuit 210 controls the voltage generating circuit 230 to provide the DC voltage DCV to the first cluster of switch (i.e., the switches SW₁ to SW₄). In this embodiment, the DC voltage DCV may switch off the transistors T1 of the pixels located on the first row to the fourth row of the pixel array 110. With such configurations, the transistors T1 of the pixels located on the fifth row to the eighth row of the pixel array 110 are switched on, and the display data carried on the data line DL described in FIG. 2 can be transmitted to the fifth row to the eighth row of the pixel array 110. Next, the operations of the control circuit 120 and the selecting circuit 130 are repeated from the embodiment of FIG. 4A.

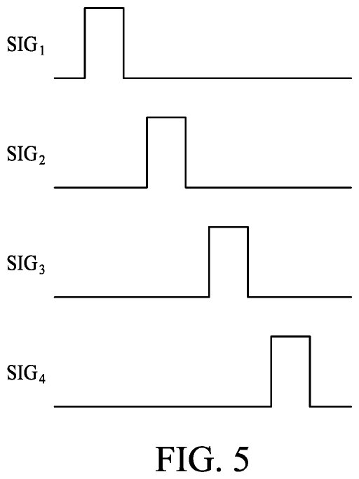

FIG. 5 is a diagram illustrating a signal waveforms of signals SIG₁ to SIG₄ generated by signal generating circuits 221 to 224 according to an embodiment of the present disclosure. As shown in FIG. 5, the signals SIG₁ to SIG₄ are sequentially asserted to a high voltage. Therefore, when the first cluster of switch (i.e., the switches SW₁ to SW₄) is activated, the transistors T1 of the pixels located on the first row to the fourth row of the pixel 110 are sequentially switched on respective by the signals SIG₁ to SIG₄. On the other hand, when the second cluster of switch (i.e., the switches SW₅ to SW₈) is activated, the transistors T1 of the pixels located on the fifth row to the eighth row of the pixel 110 are sequentially switched on respective by the signals SIG₁ to SIG₄. Those skilled in the art should readily understand the profiles of the signals SIG₁ to SIG₄ can be alternated based on the type of the transistor T1 used in the pixel array. The detailed description is omitted here for brevity.

By using the switches SW₁ to SW₈ of the selecting circuit 130 and further sequentially activating the first cluster of switch and the second cluster of switch, the amount of the signal generating circuits 221 to 22x can be greatly reduced especially when the pixel array 110 includes thousands of rows. With such configurations, the area consumed by the signal generating circuits 221 to 22x can be greatly reduced, and the saved area can be utilized for other purposes. For example, the size of the pixel array 110 can be increased.

In the embodiments of FIG. 4A and FIG. 4B, x is designed as a half of M, however, those skilled in the art should readily understand the operations of the control circuit 120 and the selecting circuit 130 shown in the embodiments of FIG. 4A and FIG. 4B can be easily derived to different number of M and x.

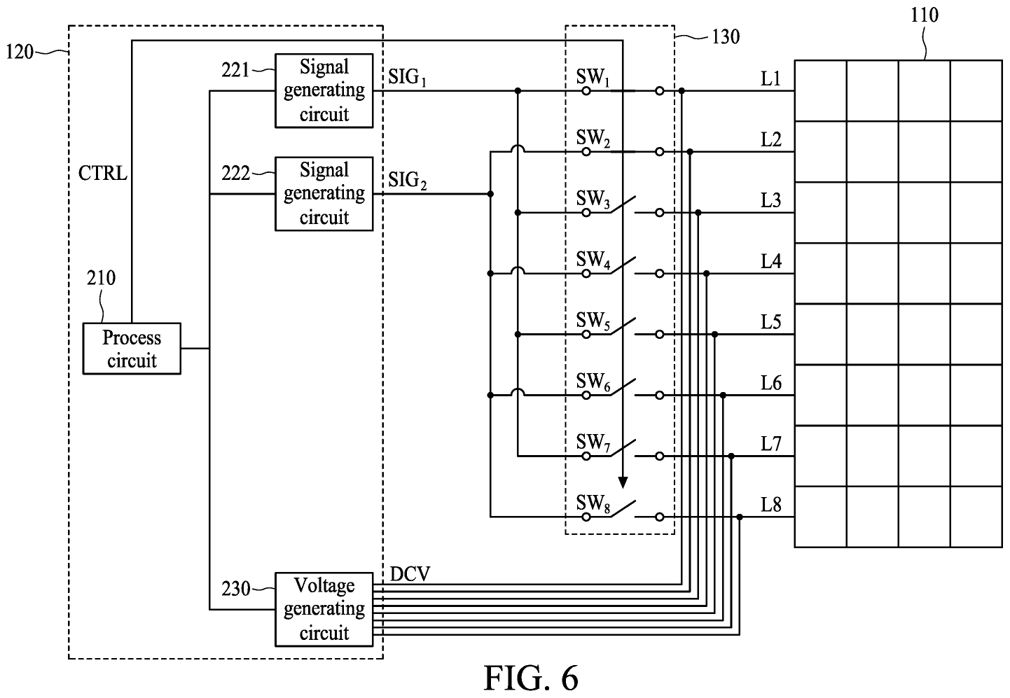

To save more area consumed by the signal generating circuits 221 to 22x, fewer signal generating circuits can be applied without sacrificing the resolution of the display panel 100. FIG. 6 is a diagram illustrating an operation of the control circuit and the selecting circuit shown in FIG. 3 according to another embodiment of the present disclosure. In this embodiment, the natural number M is 8 and the natural number x is one-fourth of M (i.e., x=2). The signal generating circuit 221 is coupled to the first row, the third row, the fifth row and the seventh row of the pixel array 110 respecitve via the switch SW₁ (with the conductive line L1), the switch SW₃ (with the conductive line L3), the switch SW₅ (with the conductive line L5) and the switch SW₇ (with the conductive line L7). The signal generating circuit 222 is coupled to the second row, the fourth row, the sixth row and the eighth row of the pixel array 110 respective via the switch SW₂ (with the conductive line L2), the switch SW₄ (with the conductive line L4), the switch SW₆ (with the conductive line L6) and the switch SW₈ (with the conductive line L8). In this embodiment, since x is one fourth of M (i.e., x=2), the switches SW₁ and SW₂ is categorized as a first cluster of switch, the switches SW₃ and SW₄ is categorized as a second cluster of switch, the switches SW₅ and SW₆ is categorized as a third cluster of switch, and the switches SW₇ to SW₈ is categorized as a fourth cluster of switch.

More specifcally, the process circuit 210 provides the control signal CTRL to activate the first cluster of switch (i.e., the switches SW₁ and SW₂) and deactivate the other clusters of switch (i.e., the switches SW₃ to SW₈). As mentioned in the embodiments of FIG. 1 and FIG. 3, each of the signals SIG₁ to SIG₄ is a pulse signal. Therefore, with the activated switch SW₁, the transistors T1 located on the first row of the pixel array 110 is switched on when the signal SIG₁ is asserted. Likewise, with the activated switch SW₂, the transistors T1 of the pixels located on the second row of the pixel array 110 is switched on when the signal SIG₂ is asserted. Meanwhile, the process circuit 210 controls the voltage generating circuit 230 to provide the DC voltage DCV to the other clusters of switch (i.e., the switches SW₃ to SW₈). In this embodiment, the DC voltage DCV may switch off the transistors T1 of the pixels located on the third row to the eighth row of the pixel array 110. With such configurations, the transistors T1 of the pixels located on the first row and the second row of the pixel array 110 are switched on, and the display data carried on the data line DL described in FIG. 2 can be transmitted to the first row and the second row of the pixel array 110.

Next, the second cluster of switch (i.e., the switches SW₃ and SW₄) is activated. Those skilled in the art should readily understand the following operations, the detailed description is omitted here for brevity. By using the switches SW₁ to SW₈ of the selecting circuit 130 and further sequentially activating four clusters of switch, fewer signal generating circuits are applied. With such configurations, the area consumed by the signal generating circuits 221 to 22x can be greatly reduced. With the faster switching speed, the display panel 100 may utilize only one signal generating circuit without sacrificaing the resolution to complete the display stage.

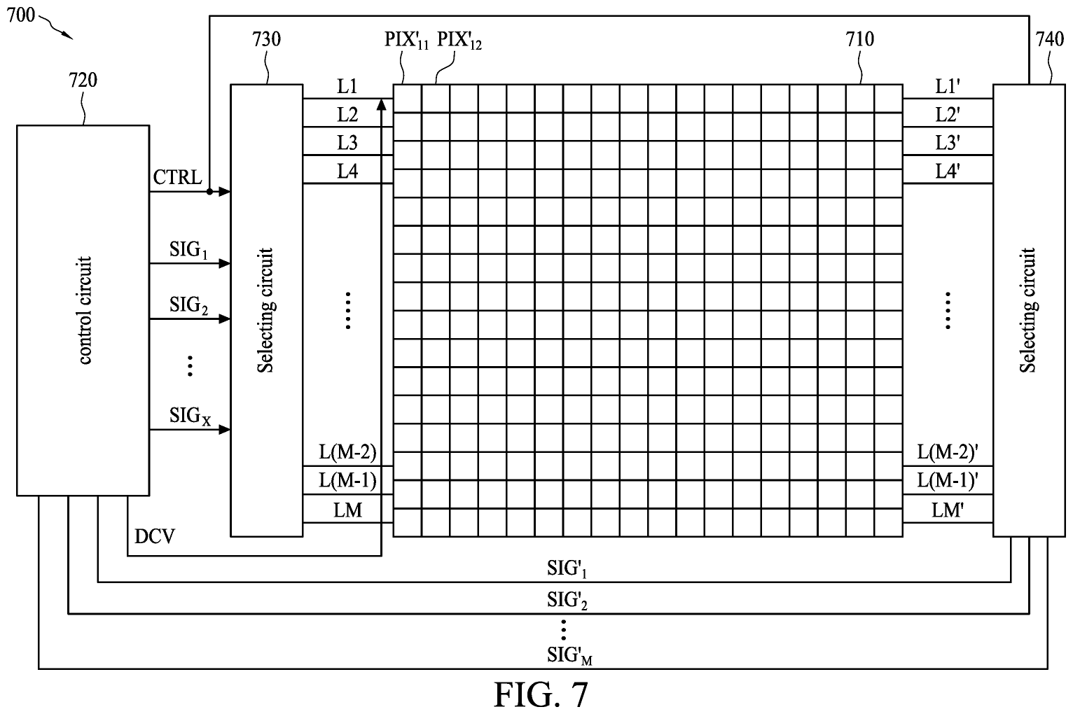

FIG. 7 is a diagram illustrating a display panel 700 according to another embodiment of the present disclosure. The display panel 700 is similar to the display panel 100 shown in FIG. 1 except the display panel 700 further includes a selecting circuit 740. Therefore, the similarity between the display panel 100 and the display panel 700 is omitted for brevity. The selecting circuit 730 couples to the pixel array 710 via conductive lines L1′ to LM′ as shown in FIG. 7, and each conductive line couples to the pixels located in the same row. The control circuit 720 provides the control signal CTRL to the selecting circuit 730 and the selecting circuit 740, and further provides signals SIG₁ to SIGₓ to the selecting circuit 730 and signals SIG′₁ to SIG′ₓ to the selecting circuit 740. As mentioned in the embodiments of FIG. 1, each of the signals SIG₁ to SIGₓ can be a pulse signal. Each of the signals SIG′₁ to SIG′ₓ can be a switch control signal which will be described later.

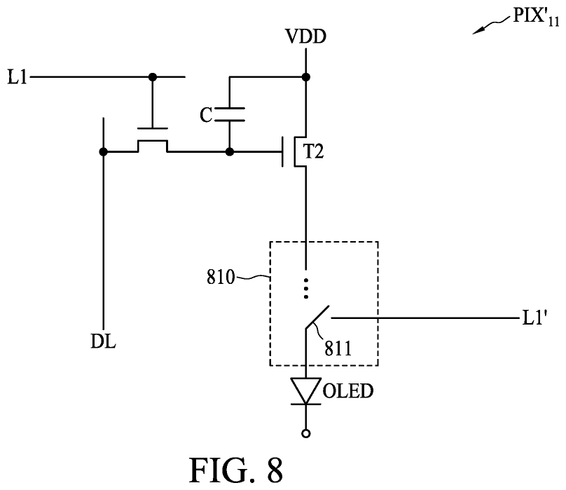

FIG. 8 is a diagram illustrating a circuit in each pixel according to another embodiment of the present disclosure. Take the pixel of the pixel array 710 for example, the pixel PIX′₁₁ is similar to the pixel PIX′₁₁ of the pixel array 210 as shown in FIG. 2 except the pixel includes a compensation circuit 810. The compensation circuit is coupled between the source terminal of the transistor T2 and the anode of the diode OLED to control the emission current based on the decay of the diode OLED. The implementation of the compensation circuit 810 should be well-known for those skilled in the art, therefore, only the part relevant to the present disclosure is depicted in FIG. 8. In this embodiment, the compensation circuit 810 includes a switch 811 controlled by a signal (e.g., the signal SIG′₁) carried on the conductive line L1′. The detailed operation of the conductive line L1′ will be described in the following paragraphs.

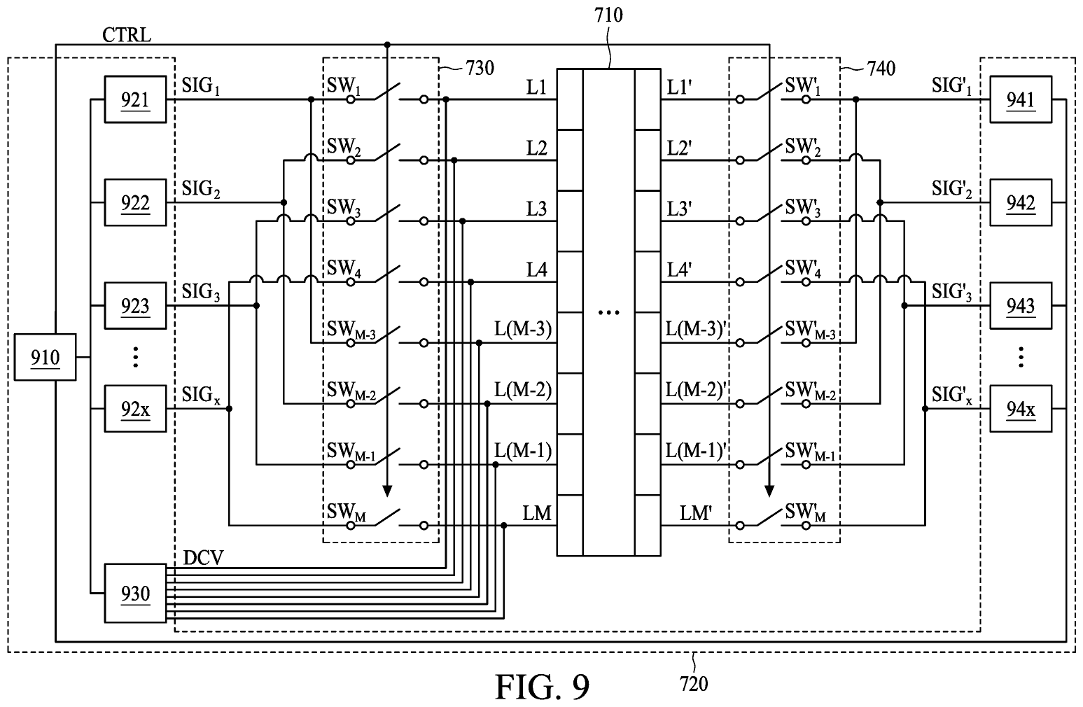

FIG. 9 is a diagram illustrating the control circuit 720 and the selecting circuits 730 and 740 according to an embodiment of the present disclosure. In this embodiment, the control circuit 720 and the selecting circuit 730 are similar to the control circuit 120 and the selecting circuit 130 described in the embodiments of FIGS. 3 except the control circuit 720 further includes signal generating circuits 941 to 94x, wherein x is a natural number smaller than M. Each of the signal generating circuits 941 to 94x generates the corresponding signal SIG′. In other words, the signal generating circuit 941 provides the signal SIG′₁, and the signal generating circuit 942 provides the signal SIG′₂, and so on. As mentioned in the embodiment of FIG. 7, each of the signals SIG′₁, to SIGₓ can be a switch control signal to control the switch 811 described in FIG. 8. The selecting circuit 740 includes switches SW′₁ to SW′_{M}, and the switch statuses of the switches SW′₁ to SW′_{M} correspond to that of the switches SW₁ to SW_{M}. In other words, via the control signal CTRL generated by the process circuit 910, the switch SW′₁ is activated when the switch SW₁ is activated. Alternatively, the switch SW′₂ is deactivated when the switch SW₁ is deactivated. The switch SW′₂ is activated when the switch SW₂ is activated, and so on. The similarity between the FIG. 3 and FIG. 9 is omitted here for brevity.

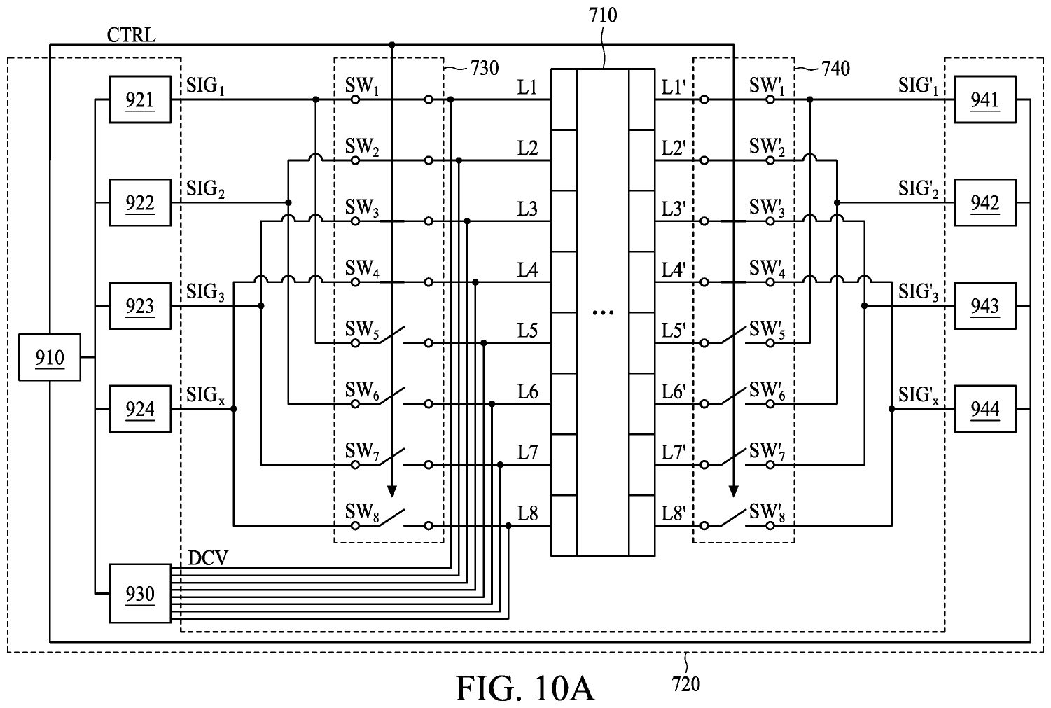

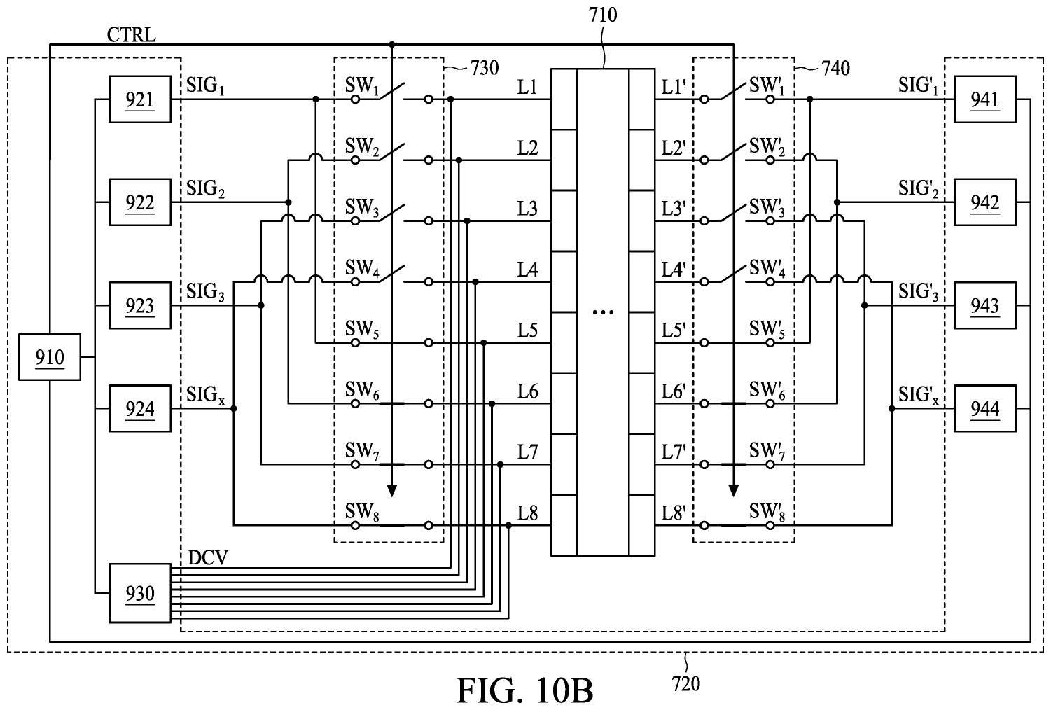

FIG. 10A is a diagram illustrating an operation of the control circuit 720 and the selecting circuits 730 and 740 shown in FIG. 9 according to an embodiment of the present disclosure. For clarity and simplicity, the natural number M is S and the natural number x is half of M (i.e., x=4). As shown in FIG. 10A, the connections between the signal generating circuits 921 to 924 and the switches SW1 to SW₈ are identical to that described in FIG. 4A, and the detailed description is omitted here for brevity. The signal generating circuit 941 is coupled to the first row and the fifth row of the pixel array 710 respecitve via the switch SW′₁ (with the conductive line L1′) and the switch SW′₅ (with the conductive line L5′). The signal generating circuit 942 is coupled to the second row and the sixth row of the pixel array 710 respecitve via the switch SW′₂ (with the conductive line L2′) and the switch SW′₆ (with the conductive line L6′). The signal generating circuit 943 is coupled to the third row and the seventh row of the pixel array 710 respecitve via the switch SW′₃ (with the conductive line L3′) and the switch SW′₇ (with the conductive line L7′). The signal generating circuit 944 is coupled to the fourth row and the eighth row of the pixel array 710 respecitve via the switch SW (with the conductive line L4′) and the switch SW′₈ (with the conductive line L8′). In this embodiment, since x is half of M (i.e., x=4), the switches SW₁ to SW₄ is categorized as a first cluster of switch while the switches SW₅ to SW₈ is categorized as a second cluster of switch. Correspondingly, the switches SW′₁ to SW′₄ is categorized as a first cluster of corresponding switch while the switches SW′₅ to SW′₈ is categorized as the second cluster of corresponding switch.

More specifcally, the process circuit 910 provides the control signal CTRL to activate the first cluster of switch (i.e., the switches SW₁ to SW₄) and the first cluster of corresponding switch (i.e., the switches SW₁ to SW′₄), and deactivate the second cluster of switch (i.e., the switches SW₅ to SW₈) and the second cluster of corresponding switch (i.e., the switches SW₅ to SW′₈). As mentioned in the embodiment of FIG. 7, each of the signals SIG₁ to SIG₄ is a pulse signal and each of the signals SIG′₁ to SIG′₄ is a switch control signal. Therefore, with the activated switch SW₁, the transistors T1 of the pixels located on the first row of the pixel array 710 is switched on when the signal SIG, is asserted. With the activated switch SW₂, the transistors T1 of the pixels located on the second row of the pixel array 710 is switched on when the signal SIG₂ is asserted, and so on. Meanwhile, with the activated switch SW′₁, the switches 811 of the pixels located on the first row of the pixel array 710 is switched on when the signal SIG′₁, is asserted. Likewise, with the activated switch SW′₂, the switches 811 of the pixels located on the second row of the pixel array 710 is switched on when the signal SIG′₂ is asserted, and so on.

The process circuit 910 controls the voltage generating circuit 930 to provide the DC voltage DCV to the second cluster of switch (i.e., the switches SW₅ to SW₈), In this embodiment, the DC voltage DCV may switch off the transistors T1 of the pixels located on the fifth row to the eighth row of the pixel array 110. With such configurations, the transistors T1 of the pixels located on the first row to the fourth row of the pixel array 110 are switched on, and the display data carried on the data line DL described in FIG. 2 can be transmitted to the first row to the fourth row of the pixel array 110.

Next, following the embodiment of FIG. 10A, FIG. 10B is a diagram illustrating a following operation of the control circuit 720 and the selecting circuits 730 and 740 shown in FIG. 9 according to an embodiment of the present disclosure. the process circuit 910 provides the control signal CTRL to activate the second cluster of switch (i.e., the switches SW₅ to SW₈) and the second cluster of corresponding switch (i.e., the switches SW′₅ to SW′₈), and deactivate the first cluster of switch (i.e., the switches SW₁ to SW₄) and the first cluster of corresponding switch (i.e., the switches SW′₁ to SW′₄). Therefore, with the activated switch SW₅, the transistors T1 located on the fifth row of the pixel array 710 is switched on when the signal SIG₅ is asserted. Likewise, with the activated switch SW₆ the transistors T1 of the pixels located on the sixth row of the pixel array 910 is switched on when the signal SIG₆ is asserted, and so on. Correspondingly, with the activated switch SW′₅, the switches 811 of the pixels located on the fifth row of the pixel array 710 is switched on when the signal SIG′₅ is asserted. Likewise, with the activated switch SW′₆, the switches 811 of the pixels located on the sixth row of the pixel array 710 is switched on when the signal SIG′₆, is asserted, and so on.

Meanwhile, the process circuit 910 controls the voltage generating circuit 930 to provide the DC voltage DCV to the first cluster of switch (i.e., the switches SW₁ to SW₄). In this embodiment, the DC voltage DCV may switch off the transistors T1 of the pixels located, on the first row to the fourth row of the pixel array 710. With such configurations, the transistors T1 of the pixels located on the fifth row to the eighth row of the pixel array 110 are switched on, and the display data carried on the data line DL described in FIG. 2 can be transmitted to the fifth row to the eighth row of the pixel array 110. Next, the operations of the control circuit 720 and the selecting circuits 730 and 740 are repeated from the embodiment of FIG. 9A.

When a part of the switches SW1 to SWM in FIGS. 3 and 9 are deactivated, for example, the second cluster of switch (i.e., the switches SW5 to SW8) is deactivated, the corresponding rows (i.e., the fifth row to the eighth row) can be configured to sense touch. For example, a detected signal sensed by the fifth row to the eighth row may be transmitted to the control circuits 120 and 720 when a user of the display panel 100 and 700 touches the fifth row to the eighth row.

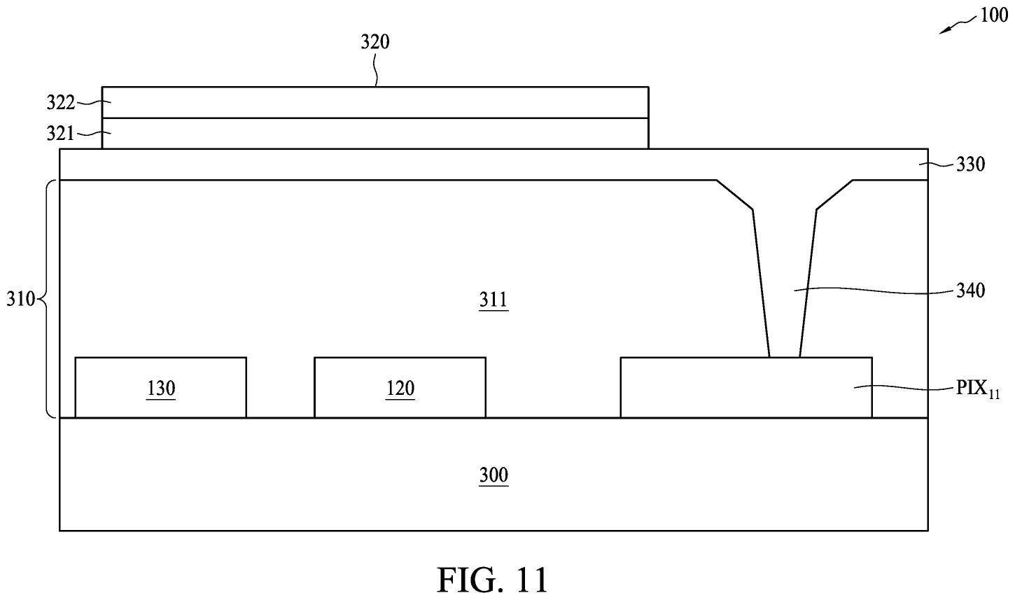

FIG. 11 is a diagram illustrating a structure of the display panel 100 according to an embodiment of the present disclosure. As shown in FIG. 1, the display panel 100 includes a substrate 300, a circuit tier 310, a light emitting layer 320, and an electrode layer 264 located between the circuit tier 310 and the light emitting layer 320. In this embodiment, the pixel array 110, the control circuit 120 and the selecting circuit 130 are formed in the circuit tier 310 on the substrate 300. Although only the pixel PIX₁₁ is depicted in FIG. 11, those skilled in the art should readily understand the structure shown in FIG. 11 can be derived to include whole pixel array. In addition, the sizes and the locations of the pixel PIX₁₁, the control circuit 120, and the selecting circuit 130 are only for illustrative purpose.

The circuit tier 310 further includes a planarization layer 311 over the pixel array 110, the control circuit 120 and the selecting circuit 130. The light emitting layer 320 is disposed on the electrode layer 330 over the planarization layer 311 as shown in FIG. 11. The light emitting layer 320 includes a carrier injection layer 321 disposed over the exposed surfaces the electrode layer 330. The carrier injection layer 321 is continuously lining along the exposed surfaces. In this embodiment, all light emitting units use a common carrier injection layer, in some embodiments, carrier injection layer 321 is for hole injection. In some embodiments, the carrier injection layer 321 is for electron injection. In some embodiments, the carrier injection layer 321 is organic.

A carrier transportation layer 322 is disposed over the exposed surfaces of the electrode 264. The carrier injection layer 321 is disposed under the carrier transportation layer 322. The carrier transportation layer 322is continuously lining along the carrier injection layer 276. In this embodiment, all light emitting units use a common carrier transportation layer 322. In some embodiments, the carrier transportation layer 322 is for hole transportation. In some embodiments, the carrier transportation layer 322 is for electron transportation. Optionally, the carrier transportation layer 322 is in contact with the carrier injection layer 321. In some embodiments, the carrier transportation layer 277 is organic.

When the circuits formed in the circuit tier 310 needs to connect to the light emitting layer 320, the contact via 340 connects the circuit to the electrode layer. For example, in the embodiment of FIG. 2, the source temrinal of the transisotr T2 connects to the anode of the diode OLED, wherein the anode of the diode OLED can be the carrier injection layer 321. Therefore, the source terminal of the transistor T2 connects to the carrier injection layer 321 via the contact via 340 and the electrode layer 330.

Those skilled in the art should readily understand the structure of the display panel 100 shown in FIG. 11 can also be applied to the display panel 700. The detailed description is omitted here for brevity.

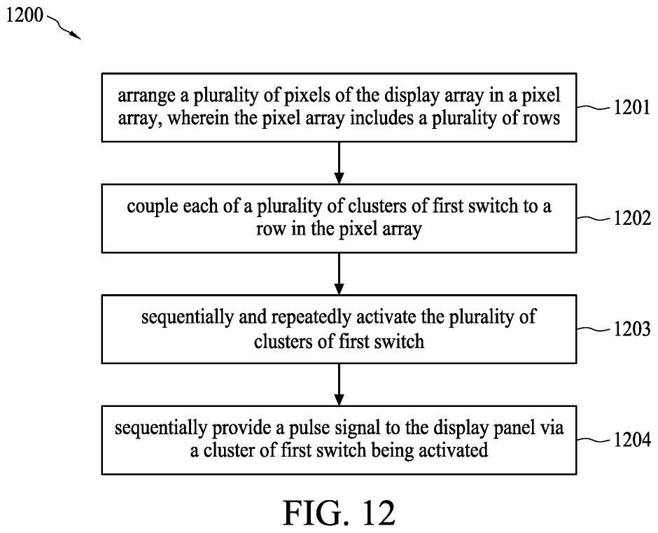

FIG. 12 is flowchart illustrating a driving method 1200 of a display panel according to an embodiment of the present disclosure. Provided that the results are substantially the same, the steps shown in FIG. 12 are not required to be executed in the exact order described, and other orders may be followed. The method 1200 is summarized as follows.

Step 1201: a plurality of pixels of the display array are arranged in a pixel array, wherein the pixel array includes a plurality of rows

Step 1202: each of a plurality of clusters of first switch is coupled to a row in the pixel array

Step 1203: the plurality of clusters of first switch are sequentia V and repeatedly activated.

Step 1204: a pulse signal to the display panel is sequentially provided via a cluster of first switch being activated

Those skilled in the art should readily understand the driving method 1200 after reading the paragraphs above. The detailed description is omitted herein for brevity.

What is claimed is:

1. A display panel, comprising:
a plurality of pixels arranged in a pixel array, wherein the pixel array includes a plurality of rows;
a first selecting circuit, coupled to the display panel, wherein the first selecting circuit includes a plurality of clusters of first switch, each first switch couples to a row, and the plurality of clusters of first switch are arranged to be sequentially and repeatedly activated; and
a control circuit, coupled to the first selecting circuit, wherein the control circuit is arranged to sequentially provide a pulse signal to the display panel via a cluster of first switch being activated;
wherein a number of the row is greater than a number of first switches in one cluster.

2. The display panel of claim 1, wherein the control circuit is further arranged to provide a direct current voltage to the rows coupled to a cluster of first switch being deactivated.

3. The display panel of claim 2, wherein the control circuit is further arranged to receive a detected signal from each of rows corresponding to the cluster of first switch being deactivated, wherein the detected signal indicates whether said each of the rows corresponding to the cluster of first switch being deactivated is touched by a user.

4. The display panel of claim 1, wherein the control circuit is arranged to provide a control signal to activate/deactivate the plurality of clusters of first switch.

5. The display panel of claim 1, wherein the control circuit comprises:
a signal generating circuit, coupled to two different rows in the pixel array via two different clusters of first switch, respectively, wherein the signal generating circuit is arranged to provide the pulse signal to the display panel via the cluster of first switch being activated.

6. The display panel of claim 1, wherein each pixel includes a transistor, and each first switch couples to the transistors in a row, and when the pulse signal is provided to gate terminals of the transistors for generating an emission current.

7-10. (canceled)

11. The display panel of claim 1, further comprising:
a circuit tier including a planarization, wherein the first selecting circuit and the control circuit are formed in the circuit tier; and
a light emitting layer over the planarization layer of the circuit tier, and including an array of light emitting pixels made by a light emitting material, wherein each of the plurality of pixels is coupled to a corresponding light emitting pixel via a conductive via.

12. A display panel, comprising:
a plurality of pixels arranged in a pixel array, wherein the pixel array includes a plurality of rows;
a first selecting circuit, including a plurality of first switches, wherein each first switch couples to a row in the pixel array;
at least one signal generating circuit, wherein each of the at least one signal generating circuit couples to at least a row in the pixel array via the first switches, and each of the at least one signal generating circuit is arranged to provide a pulse signal to the display panel; and
a process circuit, arranged to provide a control signal to the selecting circuit to activate a part of the plurality of switches and deactivate another part of the plurality of switches;
wherein a number of the rows in the pixel array is greater than a number of the at least one signal generating circuit.

13. The display panel of claim 12, further comprising:
a voltage generating circuit, arranged to provide a direct current voltage to rows coupling to switches being deactivated by the process circuit.

14. A display system, comprising:
a display panel, including:
a plurality of pixels arranged in a pixel array, wherein the pixel array includes a plurality of rows and a plurality of columns;
a first selecting circuit, coupled to the display panel, wherein the first selecting circuit includes a plurality of clusters of first switch, each first switch couples to a row, and the plurality of clusters of first switch are arranged to be sequentially and repeatedly activated; and
a control circuit, coupled to the first selecting circuit, wherein the control circuit is arranged to sequentially provide a pulse signal to the display panel via a cluster of first switch being activated;
wherein a number of the row is greater than a number of first switches in one cluster; and
a driver integrated circuit (IC), coupled to the display panel, wherein the driver IC is arranged to provide an image data to the plurality of columns in the pixel array.

15. A driving method of a display panel, comprising:
arranging a plurality of pixels of the display array in a pixel array, wherein the pixel array includes a plurality of rows;
coupling each of a plurality of clusters of first switch to a row in the pixel array;
sequentially and repeatedly activating the plurality of clusters of first switch; and
sequentially providing a pulse signal to the display panel via a cluster of first switch being activated;
wherein a number of the row is greater than a number of first switches in one cluster.

16. The method of claim 15, further comprising:
providing a direct current voltage to a cluster of first switch being deactivated.

17. The method of claim 16, further comprising:
receiving a detected signal from each of rows corresponding to the cluster of first switch being deactivated, wherein the detected signal indicates whether said each of the rows corresponding to the cluster of first switch being deactivated is touched by a user.

18-20. (canceled)
